(19) United States
(12) Patent Application Publication
(10) Pub. No.: US 2014/0252392 A1
(43) Pub. Date: Sep. 11, 2014

(54) LIGHT EMITTING DIODE

(71) Applicant: Disco Corporation, Tokyo (JP)

(72) Inventors: Minoru Suzuki, Tokyo (JP); Kota Fukaya, Tokyo (JP); Takashi Okamura, Tokyo (JP); Taro Arakawa, Tokyo (JP)

(73) Assignee: Disco Corporation, Tokyo (JP)

(21) Appl. No.: 14/184,985

(22) Filed: Feb. 20, 2014

(30) Foreign Application Priority Data
Mar. 6, 2013 (JP) 2013-044364

(51) Int. Cl. H01L 33/44

(52) U.S. Cl. CPC H01L 33/44
USPC 257/98

(57) ABSTRACT

An embodiment of the present invention provides a light emitting diode including a chip having a light emitting layer on the front surface side and a translucent member that is bonded between a back surface of the chip and a lead frame to support the chip by a resin having translucency, and is transmissive to light emitted from the light emitting layer. According to this configuration, the light emitting diode includes the translucent member that is transmissive to light emitted from the light emitting layer on the back surface side of the chip having the light emitting layer. Therefore, the ratio of light reflected at the interface with the lead frame to return to the light emitting layer can be suppressed to a low ratio and the light extraction efficiency can be enhanced.

### BACKGROUND OF THE INVENTION

1. Field of the Invention

The present invention relates to a light emitting diode including a chip in which a light emitting layer is formed.

2. Description of the Related Art

Light emitting devices such as light emitting diode (LED) and laser diode (LD) have been put into practical use. These light emitting devices normally include a light emitting chip in which a light emitting layer that emits light by application of a voltage is formed. The light emitting chip is obtained by forming a layer stack of plural semiconductor layers including the light emitting layer on a surface of a substrate for crystal growth and then arbitrarily dividing this substrate.

For example, an n-type GaN layer, an InGaN layer, and a p-type GaN layer are sequentially epitaxially grown over a surface of a sapphire substrate partitioned by a division line and electrodes connected to the n-type GaN layer and the p-type GaN layer, respectively, are formed. Thereafter, when the sapphire substrate is divided along the division line, a light emitting chip for a light emitting diode that emits blue or green light is obtained.

The light emitting diode is formed by fixing the back surface side (sapphire substrate side) of this light emitting chip to a lead frame serving as a base pedestal and covering the front surface side (layer stack side) of the light emitting chip by a lens member. For such a light emitting diode, enhancement in the luminance is considered as an important challenge and various methods for enhancing the light extraction efficiency have been proposed before (refer to e.g. Japanese Patent Laid-open No. Hei 4-10670).

### SUMMARY OF THE INVENTION

Light generated in the light emitting layer by application of a voltage is emitted mainly from two major surfaces (front surface and back surface) of the layer stack including the light emitting layer. For example, the light emitted from the front surface of the layer stack (major surface on the lens member side) is extracted to the external of the light emitting diode via the lens member and so forth. Meanwhile, the light emitted from the back surface of the layer stack (major surface on the sapphire substrate side) travels in the sapphire substrate and part thereof is reflected at the interface between the sapphire substrate and the lead frame and so forth to return to the layer stack.

For example, if a thin sapphire substrate is used for the light emitting chip for the purpose of enhancement in the processability in cutting and so forth, the distance between the back surface of the layer stack and the interface between the sapphire substrate and the lead frame becomes short. In this case, the ratio of light reflected at the interface between the sapphire substrate and the lead frame to return to the layer stack is higher than that when the sapphire substrate is thick. The layer stack absorbs light. Therefore, if a light emitting chip in which the ratio of light that returns to the layer stack is high as above is used, the light extraction efficiency of the light emitting diode is lowered.

Therefore, an object of the present invention is to provide a light emitting diode having a configuration that allows enhancement in the light extraction efficiency.

In accordance with an aspect of the present invention, there is provided a light emitting diode formed of at least a chip having a light emitting layer on a front surface side and a translucent member that is bonded between a back surface of the chip and a lead frame to support and fix the chip by a resin having translucency, and is transmissive to light emitted from the light emitting layer.

According to this configuration, the light emitting diode includes the translucent member that is transmissive to light emitted from the light emitting layer on the back surface side of the chip having the light emitting layer. Therefore, the ratio of light reflected at the interface with the lead frame to return to the light emitting layer can be suppressed to a low ratio and the light extraction efficiency can be enhanced.

In the light emitting diode of the present invention, in the chip, the light emitting layer formed of a GaN semiconductor layer may be stacked over a sapphire substrate. According to this configuration, the light extraction efficiency can be enhanced in a light emitting diode that emits blue or green light.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view schematically showing a configuration example of a light emitting diode according to the present embodiment;

FIG. 2 is a schematic sectional view showing how light is emitted from a light emitting chip of the light emitting diode according to the present embodiment;

FIG. 3 is a schematic sectional view showing how light is emitted from a light emitting chip of a light emitting diode according to a comparative example; and

FIG. 4 is a graph showing a measurement result of the luminance.

### DETAILED DESCRIPTION OF THE PREFERRED EMBODIMENT

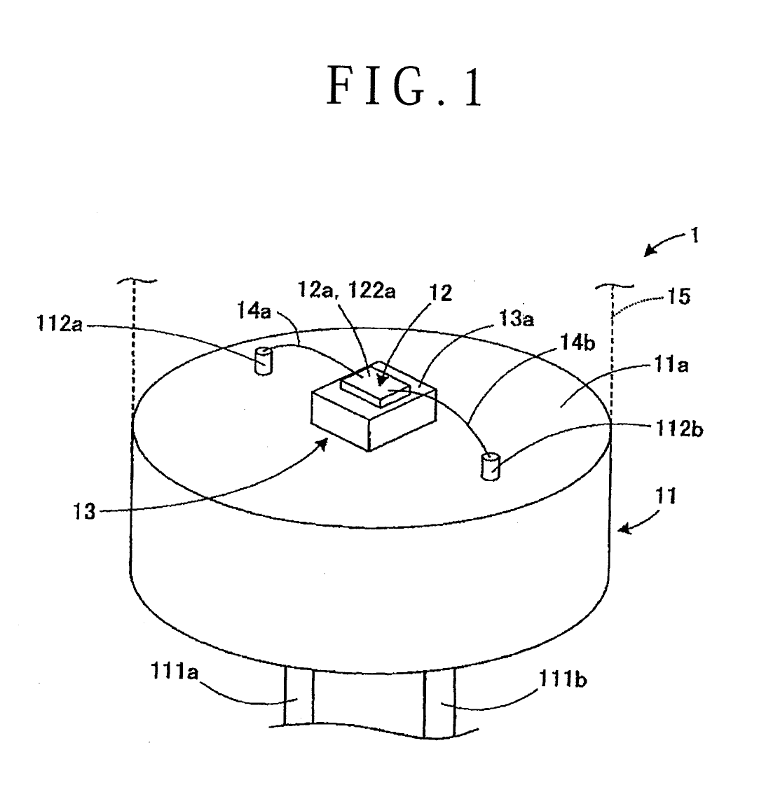

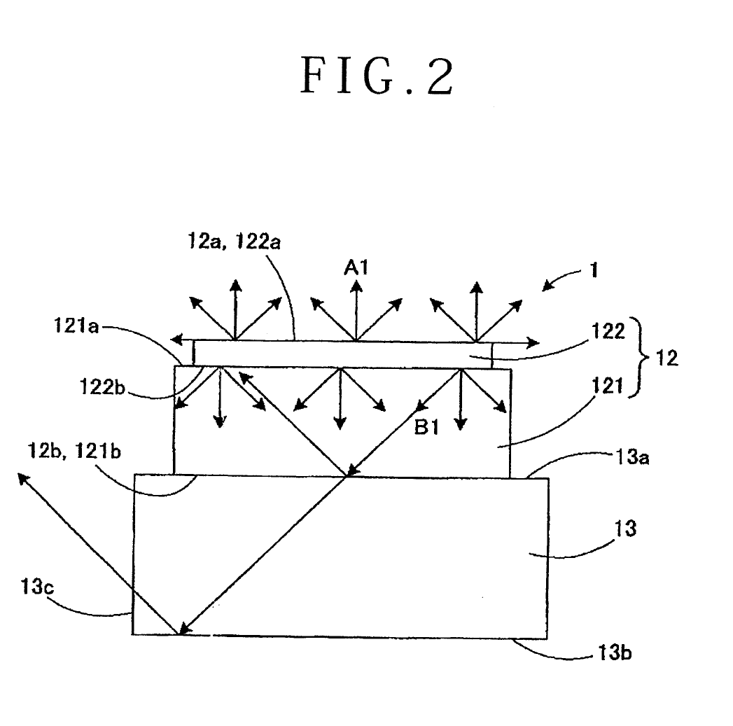

An embodiment of the present invention will be described below with reference to the accompanying drawings. FIG. 1 is a perspective view schematically showing a configuration example of a light emitting diode according to the present embodiment. FIG. 2 is a schematic sectional view showing how light is emitted from a light emitting chip of the light emitting diode according to the present embodiment. As shown in FIGS. 1 and 2, a light emitting diode 1 includes a lead frame 11 serving as a base pedestal and a light emitting chip (chip) 12 supported and fixed by the lead frame 11.

The lead frame 11 is formed into a circular column shape by a material such as a metal and two lead members 111a and 111b having electrical conductivity are provided on the side of the back surface equivalent to one major surface. The lead members 111a and 111b are insulated from each other and function as the anode and cathode, respectively, of the light emitting diode 1. The lead members 111a and 111b are connected to an external power supply (not shown) via wiring (not shown) or the like.

On a front surface 11a equivalent to the other major surface of the lead frame 11, two connection terminals 112a and 112b insulated from each other are disposed with the intermediary of a predetermined distance therebetween. The connection terminal 112a is connected to the lead member 111a inside the lead frame 11. The connection terminal 112b is connected to the lead member 111b inside the lead frame 11. Therefore, the potentials of the connection terminals 112a and 112b are equivalent to the potentials of the lead members 111a and 111b, respectively.

Over the front surface 11a of the lead frame 11, the light emitting chip 12 is disposed at a position between the connection terminal 112a and the connection terminal 112b. The light emitting chip 12 includes a sapphire substrate 121 having a rectangular shape as its planar shape and a layer stack 122 provided on a front surface 121a of the sapphire substrate 121 (FIG. 2). The layer stack 122 includes plural semiconductor layers formed by using GaN-based semiconductor materials (GaN semiconductor layers).

The layer stack 122 is formed by sequentially epitaxially growing an n-type semiconductor layer (e.g. an n-type GaN layer), in which electrons are the majority carriers, a semiconductor layer (e.g. an InGaN layer) to serve as a light emitting layer, and a p-type semiconductor layer (e.g. a p-type GaN layer), in which holes are the majority carriers. Furthermore, on the sapphire substrate 121, two electrodes (not shown) that are connected to the n-type semiconductor layer and the p-type semiconductor layer, respectively, and apply a voltage to the layer stack 122 are formed. These electrodes may be included in the layer stack 122.

A translucent member 13 having a rectangular parallelepiped shape is disposed on the side of a back surface 121b of the sapphire substrate 121 (e.g. on the side of a back surface 12b of the light emitting chip 12). The translucent member 13 is formed of a material such as glass or resin and is transmissive to light radiated from the light emitting layer of the layer stack 122. The area of a front surface 13a of the translucent member 13 is larger than that of the back surface 121b of the sapphire substrate 121. It is preferable for the translucent member 13 to have a thickness equivalent to or larger than that of the sapphire substrate 121.

The front surface 13a of the translucent member 13 is bonded to the whole of the back surface 121b of the sapphire substrate 121 (e.g. the back surface 12b of the light emitting chip 12) by a resin (not shown) having translucency. Furthermore, a back surface 13b of the translucent member 13 is bonded to the front surface 11a of the lead frame 11 by a resin (not shown) having translucency. That is, the light emitting chip 12 is fixed to the front surface 11a of the lead frame 11 with the intermediary of the translucent member 13.

The two connection terminals 112a and 112b provided on the lead frame 11 are connected to the two electrodes of the light emitting chip 12 via lead wires 14a and 14b, respectively, having electrical conductivity. Due to this, the voltage of the power supply connected to the lead members 111a and 111b is applied to the layer stack 122. When the voltage is applied to the layer stack 122, electrons flow from the n-type semiconductor layer into the semiconductor layer serving as the light emitting layer and holes flow from the p-type semiconductor layer into it. As a result, the recombination of the electrons and the holes occurs in the semiconductor layer serving as the light emitting layer and light having a predetermined wavelength is emitted. In the present embodiment, because the semiconductor layer serving as the light emitting layer is formed by using a GaN-based semiconductor material, blue or green light corresponding to the band gap of the GaN-based semiconductor material is emitted.

A dome-shaped lens member 15 covering the side of the front surface 12a of the light emitting chip 12 is attached to the circumferential edge of the side of the front surface 11a of the lead frame 11. The lens member 15 is formed of a material, such as a resin, having a predetermined refractive index and refracts the light emitted from the layer stack 122 of the light emitting chip 12 to guide the light to the external of the light emitting diode 1 along predetermined directions. In this manner, the light emitted from the light emitting chip 12 is extracted to the external of the light emitting diode 1 via the lens member 15.

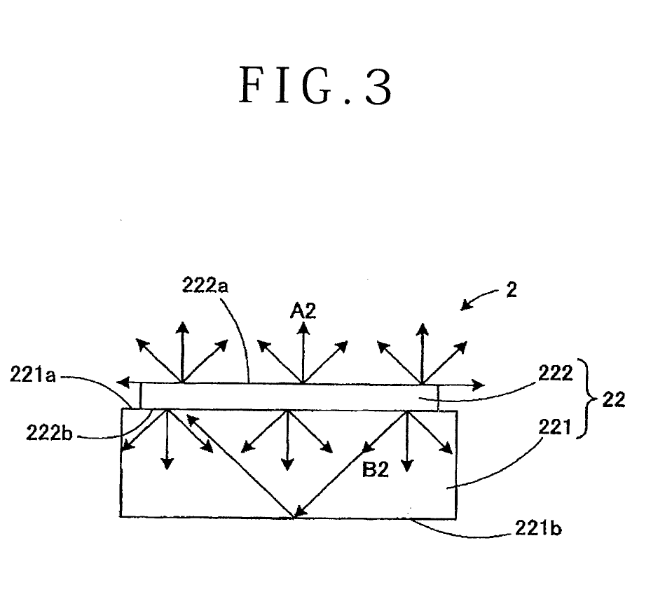

Next, how light is extracted from the light emitting chip 12 in the light emitting diode 1 according to the present embodiment will be described with reference to a light emitting diode according to a comparative example. FIG. 3 is a schematic sectional view showing how light is emitted from a light emitting chip of the light emitting diode according to the comparative example. As shown in FIG. 3, a light emitting diode 2 according to the comparative example has a configuration common to the light emitting diode 1 according to the present embodiment except for the translucent member 13. Specifically, the light emitting diode 2 includes a light emitting chip 22 including a sapphire substrate 221 having a rectangular shape as its planar shape and a layer stack 222 provided on a front surface 221a of the sapphire substrate 221. However, a back surface 221b of the sapphire substrate 221 is bonded to a lead frame (not shown).

In the light emitting diode 1 according to the present embodiment, light generated in the semiconductor layer serving as the light emitting layer is emitted mainly from the front surface 122a of the layer stack 122 (i.e. the front surface 12a of the light emitting chip 12) and the back surface 122b. The light emitted from the front surface 122a of the layer stack 122 (e.g. light traveling on an optical path A1) is extracted to the external of the light emitting diode 1 via the lens member 15 and so forth as described above.

This is the same also in the light emitting diode 2 according to the comparative example. Specifically, in the light emitting diode 2, light generated in the semiconductor layer serving as the light emitting layer is emitted mainly from a front surface 222a and a back surface 222b of the layer stack 222. The light emitted from the front surface 222a of the layer stack 222 (e.g. light traveling on an optical path A2) is extracted to the external of the light emitting diode 2 via a lens member (not shown) and so forth.

Meanwhile, in the light emitting diode 2, part of the light emitted from the back surface 222b of the layer stack 222 (e.g. light traveling on an optical path B2) is reflected at the interface between the sapphire substrate 221 and the lead frame (the back surface 221b of the sapphire substrate 221) to return to the layer stack 222. The layer stack 222 absorbs light. Therefore, in the light emitting diode 2 according to the comparative example, the light traveling on the optical path B2 cannot be extracted to the external.

In contrast, in the light emitting diode 1 according to the present embodiment, the translucent member 13 is provided under the back surface 121b of the sapphire substrate 121 with the intermediary of the resin having translucency and thus light emitted from the back surface 122b of the layer stack 122 travels on optical paths different from those in the light emitting diode 2. For example, part of light traveling on an optical path B1 is reflected at the interface between the sapphire substrate 121 and the translucent member 13 (i.e. the back surface 121b of the sapphire substrate 121 or the front surface 13a of the translucent member 13). Furthermore, another part of the light traveling on the optical path B1 passes through the interface between the sapphire substrate 121 and the translucent member 13. In this manner, part of the light traveling on the optical path B1 is absorbed by the layer stack 122 similarly to in the light emitting diode 2 whereas another part of the light traveling on the optical path B1 is extracted to the external from a side surface 13c of the translucent member 13 and so forth.

As above, the light emitting diode 1 according to the present embodiment includes the translucent member 13 that is transmissive to light emitted from the light emitting layer on the side of the back surface 12b of the light emitting chip (chip) 12 having the layer stack 122 including the light emitting layer on the side of the front surface 12a. Thus, the ratio of light reflected at the interface with the lead frame 11 to return to the light emitting layer (the layer stack 122) can be suppressed to a low ratio and the light extraction efficiency can be enhanced.

The sapphire substrate is so hard as not to be easily processed and therefore it is preferable to use a thin sapphire substrate to enhance the processability. In this case, in the light emitting diode 2 of the comparative example, the distance between the back surface 222b of the layer stack 222 and the interface between the sapphire substrate 221 and the lead frame is shortened and the ratio of light reflected at this interface to return to the layer stack 222 becomes higher. Thus, the light extraction efficiency is lowered. In contrast, in the light emitting diode 1 according to the present embodiment, the light extraction efficiency can be kept high by the translucent member 13 even when the thickness of the sapphire substrate 121 is reduced. That is, there is no need to increase the thickness of the sapphire substrate for keeping the light extraction efficiency to sacrifice the processability.

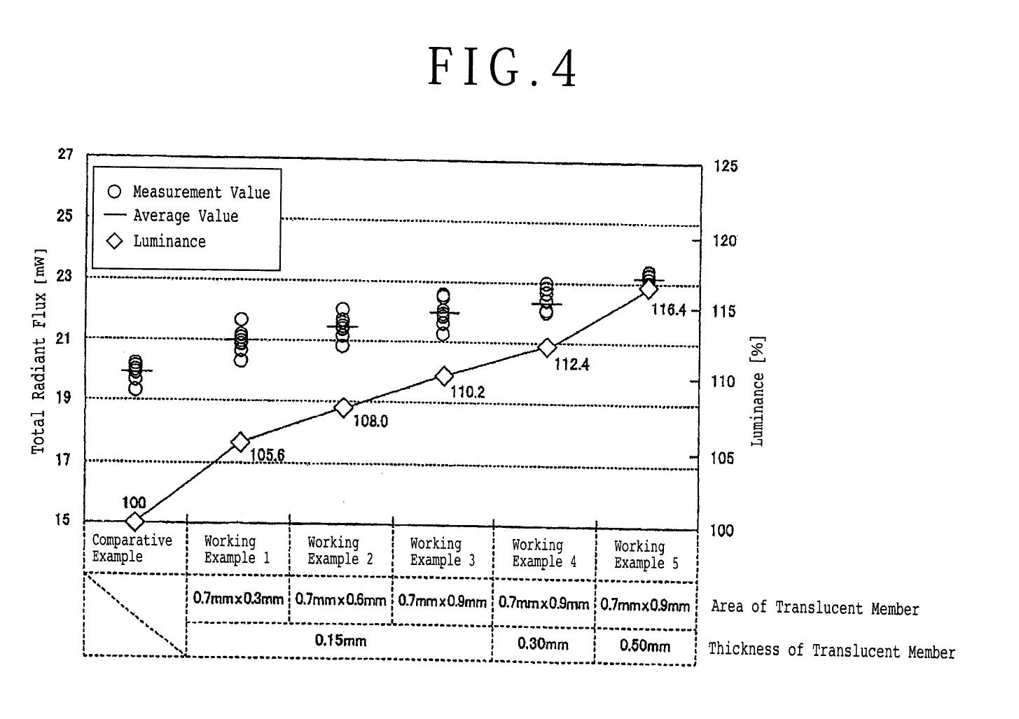

Next, an experiment carried out in order to check the effectiveness of the light emitting diode 1 according to the present embodiment will be described. In this experiment, the luminance of plural light emitting diodes each having a respective one of translucent members different from each other in size was measured. Specifically, the total value of the intensity (power) of all light radiated from each light emitting diode was measured (total radiant flux measurement) and converted into the luminance calculated with the comparative example using no translucent member regarded as the criterion (100%). FIG. 4 is a graph showing the measurement result. In FIG. 4, the ordinate indicates the total radiant flux (mW) or the luminance (%) of each light emitting diode.

As shown in FIG. 4, in this experiment, the luminance was measured about five kinds of light emitting diodes using the translucent member (working examples 1 to 5) and a light emitting diode using no translucent member (comparative example). A common light emitting chip was used in all of working examples 1 to 5 and the comparative example. Specifically, a light emitting chip was used in which a light emitting layer formed of a GaN semiconductor layer was formed over a sapphire substrate having an area of 0.595 mm×0.270 mm as the area of the front surface and back surface (vertical×horizontal) and having a thickness (height) of 0.15 mm. Bonding between the sapphire substrate and the translucent member was made by using an adhesive made of a resin having sufficiently low absorbance.

In working example 1, a glass substrate having an area of 0.7 mm×0.3 mm as the area of the front surface and back surface (vertical×horizontal) and having a thickness (height) of 0.15 mm was used as the translucent member. In working example 2, a glass substrate having an area of 0.7 mm×0.6 mm as the area of the front surface and back surface and having a thickness of 0.15 mm was used as the translucent member. In working example 3, a glass substrate having an area of 0.7 mm×0.9 mm as the area of the front surface and back surface and having a thickness of 0.15 mm was used as the translucent member. In working example 4, a glass substrate having an area of 0.7 mm×0.9 mm as the area of the front surface and back surface and having a thickness of 0.30 mm was used as the translucent member. In working example 5, a glass substrate having an area of 0.7 mm×0.9 mm as the area of the front surface and back surface and having a thickness of 0.50 mm was used as the translucent member. In working example 4, two glass substrates of working example 3 were attached to each other to make the translucent member.

As shown in FIG. 4, providing the translucent member on the back surface side of the light emitting chip can enhance the light extraction efficiency. Furthermore, a tendency could be checked out that a larger area of the front surface and back surface of the translucent member provided higher luminance of the light emitting diode and a larger thickness of the translucent member provided higher luminance of the light emitting diode. It is preferable for the translucent member to be formed with a large size within such a range as not to affect mounting onto the lead frame.

The present invention is not limited to the description of the above embodiment and can be carried out with various changes. For example, although a light emitting chip using a sapphire substrate and a GaN-based semiconductor material is exemplified in the above embodiment, the substrate for crystal growth and the semiconductor material are not limited thereto. Although it is preferable to reduce the thickness of the substrate for crystal growth, such as a sapphire substrate, to enhance the processability, the substrate for crystal growth does not necessarily need to be thin.

Furthermore, although the layer stack 122 in which an n-type semiconductor layer, a semiconductor layer serving as a light emitting layer, and a p-type semiconductor layer are sequentially provided is exemplified in the above embodiment, the configuration of the layer stack 122 is not limited thereto. It is enough for the layer stack 122 to be so configured as to be capable of at least emission of light through the recombination of electrons and holes. Besides, configurations, methods, and so forth according to the above embodiment can be carried out with appropriate changes without departing from the scope of the object of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A light emitting diode comprising:
a chip having a light emitting layer on a front surface side; and
a translucent member that is bonded between a back surface of the chip and a lead frame to support and fix the chip by a resin having translucency, and is transmissive to light emitted from the light emitting layer.

2. The light emitting diode according to claim 1, wherein
the chip is formed by stacking the light emitting layer formed of a GaN semiconductor layer over a sapphire substrate.
